(19) United States
(12) Patent Application Publication
(10) Pub. No.: US 2011/0128806 A1
(43) Pub. Date: Jun. 2, 2011

(54) SEMICONDUCTOR INTEGRATED CIRCUIT TEST METHOD AND SEMICONDUCTOR INTEGRATED CIRCUIT

(75) Inventor: Toshio Takeshima, Kanagawa (JP)

(73) Assignee: Renesas Electronics Corporation

(21) Appl. No.: 12/949,063

(22) Filed: Nov. 18, 2010

(30) Foreign Application Priority Data
Dec. 2, 2009 (JP) 2009-274252

(51) Int. Cl. G11C 29/00

(52) U.S. Cl. 365/201

(57) ABSTRACT

In a semiconductor integrated circuit having multiple memory macros, a memory macro test is carried out with high accuracy within a short period of time. A semiconductor integrated circuit test method according to one aspect of the present invention is applicable to inspection of a semiconductor integrated circuit having multiple memory macros, wherein the number of memory macros to be selected in execution of a simultaneous read-out operation for simultaneously reading out written test data is smaller than the number of memory macros to be selected in execution of a simultaneous write-in operation for simultaneously writing in input test data.

### CROSS-REFERENCE TO RELATED APPLICATIONS

The disclosure of Japanese Patent Application No. 2009-274252 filed on Dec. 2, 2009 including the specification, drawings and abstract is incorporated herein by reference in its entirety.

### BACKGROUND OF THE INVENTION

The present invention relates to a semiconductor integrated circuit test method and a semiconductor integrated circuit, and more particularly to a semiconductor integrated circuit test method for inspecting a semiconductor integrated circuit having multiple memory macros.

In recent years, with increases in integration density and functional complexity of semiconductor integrated circuits such as system LSI (Large Scale Integrated) circuits, it has become common practice to carry out circuit design on the basis of each circuit block having certain functions (hereinafter referred to as a “macro” wherever appropriate). Thus, in prevalent practice of circuit design, multiple memory macros are incorporated in a semiconductor integrated circuit. A memory macro is provided as a RAM (Random Access Memory), a ROM (Read Only Memory) or the like wherein a sense amplifier and a write amplifier are included for each memory cell array block (Japanese Unexamined Patent Publication No. 2006-140389: Patent Document 1).

In a test of a semiconductor integrated circuit having multiple memory macros, a period of test time increases if the memory macros are inspected sequentially. In Japanese Unexamined Patent Publication No. 2001-266594 (Patent Document 2), there is disclosed a technique intended for efficient implementation of a pause test of multiple memory macros contained in a semiconductor integrated circuit. According to the technique for testing memory macros contained in the semiconductor integrated circuit disclosed in the Patent Document 2, simultaneous write-in processing is performed on a predetermined number of memory macros, and until completion of the simultaneous write-in processing on all the predetermined memory macros, the other memory macros are put in test-suspended states. Then, at the end of the simultaneous write-in processing on all the predetermined memory macros, the testing is resumed for reading-out, i.e., simultaneous read-out processing is performed thereon.

### SUMMARY OF THE INVENTION

However, if multiple memory macros are simultaneously operated in a memory macro test as described in the Patent Document 2, there arises a problem that accurate test results cannot be obtained. Due to simultaneous operation of the memory macros, power noise occurs to cause an adverse effect on test results. In particular, the degree of adverse effect caused by power noise on test results in read-out processing is larger than that in write-in processing. Hence, in the technique disclosed in the Patent Document 2, even if the memory macros are operated normally in simultaneous writing thereto, there is a high degree of possibility that accurate test results may not be obtained in simultaneous reading therefrom.

More specifically, in write-in operation, data to be written into each memory macro is input from external circuitry to a write amplifier, and then the input data is propagated, as a signal having a large difference potential, from the write amplifier to a memory cell through a bit line. Thus, in the write-in operation, a noise margin is relatively large since a signal level on the bit line of the memory macro has a relatively large amplitude. Contrastingly, in read-out operation, data read out of each memory cell is propagated, as a signal having a relatively small difference potential, to a sense amplifier through a bit line for output to the external circuitry. Thus, in the read-out operation, a noise margin is relatively small since a signal level on the bit line of the memory macro has a relatively small amplitude (in comparison with the write-in operation). Hence, if the number of memory macros operated simultaneously in the write-in operation is equal to the number of memory macros operated simultaneously in the read-out operation, test results in the read-out operation may become inaccurate due to an adverse effect of power noise.

In carrying out the present invention and according to one aspect thereof, there is provided a semiconductor integrated circuit test method for inspecting a semiconductor integrated circuit having multiple memory macros, wherein the number of memory macros to be selected in execution of a simultaneous read-out operation for simultaneously reading out test data is smaller than the number of memory macros to be selected in execution of a simultaneous write-in operation for simultaneously writing in test data.

Further, according to another aspect of the present invention, there is provided a semiconductor integrated circuit having multiple memory macros, the semiconductor integrated circuit comprising: an operation control circuit for selecting operation-object memory macros from the memory macros; and a test circuit for carrying out simultaneous write-in processing in which test data is simultaneously written into memory macros selected by the operation control circuit, and for carrying out simultaneous read-out processing in which test data is simultaneously read out of memory macros selected by the operation control circuit; wherein the number of operation-object memory macros to be selected by the operation control circuit in execution of the simultaneous read-out processing is smaller than the number of operation-object memory macros to be selected by the operation control circuit in execution of the simultaneous write-in processing.

In the above-mentioned aspects of the present invention, a simultaneous write-in operation is performed on multiple memory macros. In the write-in operation, since a write-in data signal propagating through a bit line has a relatively large difference potential, the level of immunity to power noise is higher than that in data reading-out, i.e., the write-in operation is less susceptible to interference due to operational simultaneity. Thereafter, a simultaneous read-out operation is performed on partial memory macros that have been subjected to the write-in operation. In the read-out operation, since the number of memory macros operated simultaneously is smaller than that in data writing-in, the occurrence of power noise can be suppressed. Thus, in the read-out operation in which a read-out data signal propagating through a bit line has a relatively small difference potential, an adverse effect of power noise is reduced.

As set forth above and according to the present invention, in a semiconductor integrated circuit having multiple memory macros, it is possible to conduct a memory macro test with high accuracy within a short period of time.

### BRIEF DESCRIPTION OF THE DRAWINGS

FIG. 1 is a block diagram showing a configuration of a semiconductor integrated circuit according to a first embodiment of the present invention;

FIG. 2 is a block diagram showing a configuration of a memory macro according to the first embodiment of the present invention;

FIG. 3 is a flowchart showing procedural steps of a memory macro test method according to the first embodiment of the present invention;

FIG. 4 is an explanatory diagram showing an example of memory macro selection according to a working example 1 of the first embodiment of the present invention;

FIG. 5 is a flowchart showing procedural steps of a memory macro test method according to the working example 1 of the first embodiment of the present invention;

FIG. 6 is an explanatory diagram showing an example of memory macro selection according to a working example 2 of the first embodiment of the present invention;

FIG. 7 is a flowchart showing procedural steps of a memory macro test method according to the working example 2 of the first embodiment of the present invention;

FIG. 8 is an explanatory diagram showing an example of memory macro selection according to a working example 3 of the first embodiment of the present invention;

FIG. 9 is a flowchart showing procedural steps of a memory macro test method according to the working example 3 of the first embodiment of the present invention;

FIG. 10 is a block diagram showing a configuration of a semiconductor integrated circuit according to a second embodiment of the present invention; and

FIG. 11 is a block diagram showing a configuration of a semiconductor integrated circuit according to a third embodiment of the present invention.

### DETAILED DESCRIPTION OF THE PREFERRED EMBODIMENTS

The present invention will now be described in detail with respect to specific embodiments and working examples thereof with reference to the accompanying drawings. Throughout the accompanying drawings, like reference characters designate like or corresponding parts to avoid repetitive description thereof wherever appropriate for the sake of clarity.

### First Embodiment

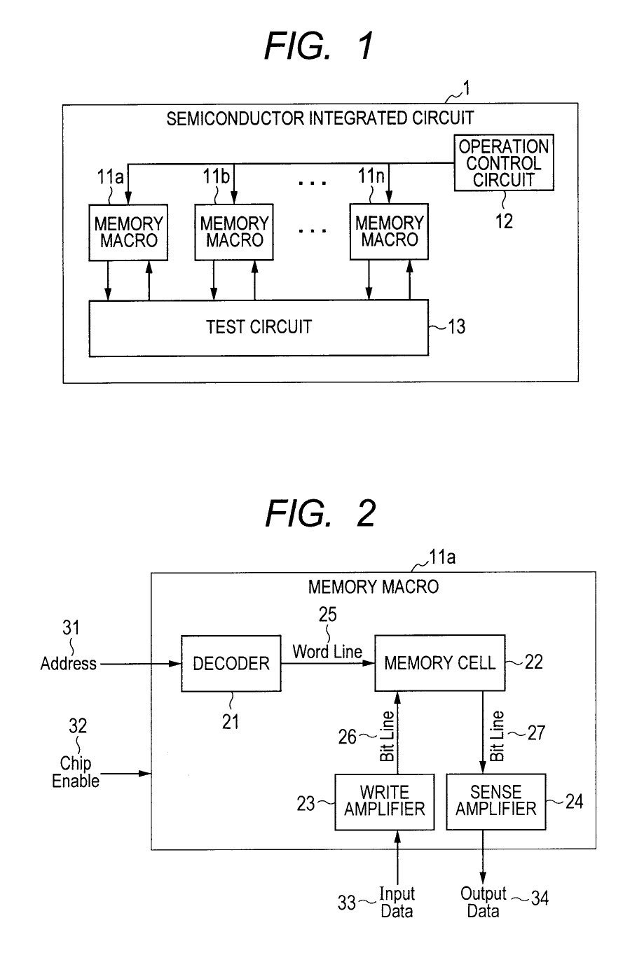

Referring to FIG. 1, there is shown a block diagram of a configuration of a semiconductor integrated circuit 1 according to a first embodiment of the present invention. The semiconductor integrated circuit 1 comprises a memory macro 11a, memory macros 11b, . . . , and 11n, an operation control circuit 12, and a test circuit 13. The semiconductor integrated circuit 1 is designed as a system LSI circuit, for example. Further, although not shown in FIG. 1, the semiconductor integrated circuit 1 includes multiple power supply lines. Through the power supply lines, power is fed to the memory macros 11a, 11b, . . . , and 11n, the operation control circuit 12, and the test circuit 13.

The memory macros 11a, 11b, . . . , and 11n are so-called semiconductor memories such as SRAMs (Static Random Access Memories). Herein, it is conditioned that at least two memory macros are contained in the semiconductor integrated circuit 1. FIG. 2 shows a block diagram of a configuration of the memory macro 11a according to the first embodiment of the present invention. The configurations of the memory macros 11b, . . . , and 11n are equivalent to that shown in FIG. 2, and therefore, no duplicative illustrations and descriptions thereof are given here.

The memory macro 11a comprises a decoder 21, a memory cell 22, a write amplifier 23, and a sense amplifier 24, at least in principle. Note that the memory macro 11a may include other component elements not shown in FIG. 2. The memory macro 11a receives an address 31, a chip enable signal 32, and input data 33 from external circuitry, and delivers output data 34 as read-out data.

The address 31 indicates a location address of a data storage region that is a read-out or write-in object in the memory cell 22. The chip enable signal 32 indicates whether the operation of the memory macro 11a itself is allowed or not, i.e., the chip enable signal 32 indicates whether or not to activate the memory macro 11a. Note that the chip enable signal 32 may contain information indicating a write-enabled/disabled state. The input data 33 is object data to be written into the memory macro 11a. The output data 34 is object data to be read out of a storage region corresponding to the address 31.

The decoder 21 receives the address 31 input from the external circuitry, decodes the received address 31, and selects a word line 25 according to the result of decoding the address 31.

The memory cell 22 is a storage device for storing data for each address. In the memory cell 22, there are disposed extensions of word lines 25, and extensions of bit lines 26 and 27. Further, in the memory cell 22, a write-in or read-out object region is identified through a word line 25 selected by the decoder 21. That is, in a data write-in operation, the address 31 specifies a write-in object region in the memory cell 22, and in a data read-out operation, the address 31 specifies a read-out object region in the memory cell 22.

The write amplifier 23 receives the input data 33 from the external circuitry, and feeds the received input data to the memory cell 22 through the bit line 26. Then, the write amplifier 23 carries out writing the input data 33 into a write-in object region specified by the input address 31. Note that, in a data write-in operation, the write-in data concerned is provided from the write amplifier 23 as a signal having a large difference potential, which is propagated to the memory cell 22 through the bit line 26.

In the first embodiment of the present invention, the term “write-in operation” signifies a series of actions wherein a write-in object region in the memory cell 22 specified by the address 31 is identified, the write amplifier 23 receives the input data 33 from the external circuitry, and then the input data 33 is set up in the write-in object region through the bit line 26. For example, in a write-in operation involving data rewriting, a data value stored in a write-in object region in the memory cell 22 specified by the address 31 is inverted. Contrastingly, in a write-in operation not involving data rewriting, a write-in processing is accomplished without data value inversion, differently from the case of the write-in operation involving data rewriting.

Further, in the first embodiment of the present invention, the term “simultaneous write-in operation” for simultaneously writing in test data signifies that the above-mentioned write-in operations are performed simultaneously in multiple memory macros. In each of the memory macros 11a, 11b, . . . , and 11n, a data write-in operation is carried out by propagation of a signal having a large difference potential through the bit line 26. That is, a noise margin is relatively large in a simultaneous write-in operation in the memory macros 11a, 11b, . . . , and 11n.

The sense amplifier 24 receives data output from the memory cell 22 through the bit line 27, and delivers the data as output data 34 to the external circuitry. That is, the sense amplifier 24 reads out data stored in a read-out object region in the memory cell 22 specified by the input address 31. Note that, in a data read-out operation, the read-out data concerned is provided from the memory cell 22 as a signal having a small difference potential, which is propagated to the sense amplifier 24.

In the first embodiment of the present invention, the term “read-out operation” signifies a series of actions wherein a read-out object region in the memory cell 22 specified by the address 31 is identified, the sense amplifier 24 receives output data stored in the read-out object region from the memory cell 22 through the bit line 27, and then the sense amplifier 24 outputs the received output data to the external circuitry.

Further, in the first embodiment of the present invention, the term “simultaneous read-out operation” for simultaneously reading out test data signifies that the above-mentioned read-out operations are performed simultaneously in multiple memory macros. In each of the memory macros 11a, 11b, . . . , and 11n, a data read-out operation is carried out by propagation of a signal having a small difference potential through the bit line 27. That is, a noise margin is relatively small in a simultaneous read-out operation in the memory macros 11a, 11b, . . . , and 11n as compared with the case of a simultaneous write-in operation under a condition where an equal number of memory macros are operated.

From the memory macros 11a, 11b, . . . , and 11n, the operation control circuit 12 selects operation-object memory macros in each of simultaneous write-in and read-out operations. More specifically, the operation control circuit 12 selects a smaller number of operation-object memory macros in execution of a simultaneous read-out operation than the number of operation-object memory macros in execution of a simultaneous write-in operation. That is, the operation control circuit 12 selects, as a group of operation objects of write-in processing, a first memory group of at least two memory macros from multiple memory macros contained in the semiconductor integrated circuit 1. Further, the operation control circuit 12 selects, as a group of operation objects of read-out processing, a second memory group of partial memory macros included in the first memory group from the memory macros contained in the semiconductor integrated circuit 1. For example, the operation control circuit 12 is preferably arranged to select a group of operation objects by activating memory macro operations. In more detailed terms, the operation control circuit 12 issues the chip enable signal 32 to the memory macros belonging to the first memory group for activating operations thereof.

In the operation control circuit 12, there may be preregistered information regarding definitions of the first memory group, the second memory group, and other specific memory groups. Alternatively, there may be provided such an arrangement that the operation control circuit 12 receives a memory group selection instruction from external circuitry of the semiconductor integrated circuit 1, and selects a particular memory group according to the instruction thus received. In either case, the operation control circuit 12 is preferably equipped with registers or the like for storing definitions of specific memory groups. Further, it is preferable that, after selecting a specific memory group, the operation control circuit 12 should provide notification thereof to the test circuit 13 on an each-time basis.

The test circuit 13 carries out simultaneous write-in processing for simultaneously writing test data into memory macros selected by the operation control circuit 12, and also carries out simultaneous read-out processing for simultaneously reading test data out of memory macros selected by the operation control circuit 12. For example, in a situation where the first memory group is selected by the operation control circuit 12, the test circuit 13 carries out simultaneous write-in processing for simultaneously writing test data into the first memory group. The test circuit 13 is preferably arranged in the form of a Built-In Self-Test (BIST) circuit, for example.

Further, there may be provided such an arrangement that the test circuit 13 receives notification of a selected group of memory macros from the operation control circuit 12. Alternatively, in the test circuit 13, there may be preregistered information regarding definitions of specific memory groups. At least in principle, the test circuit 13 is arranged to verify test data read out of a selected group of memory macros. Thus, multiple memory macros contained in the semiconductor integrated circuit 1 can be tested.

In execution of “simultaneous test data write-in processing by the test circuit 13”, multiple addresses are input with respect to multiple memory macros, and data write-in processing is performed on the addresses by using input data fed from the test circuit 13 in the same time frame. Further, in execution of “simultaneous test data read-out processing by the test circuit 13”, multiple addresses are input with respect to multiple memory macros, and data read-out processing is performed on the memory macros to read out data therefrom in the same time frame.

That is, in “simultaneous write-in processing” according to the first embodiment of the present invention, the test circuit 13 performs the above-mentioned simultaneous write-in operation on at least two of the memory macros 11a, 11b, . . . , and 11n. Further, in “simultaneous read-out processing” according to the present first embodiment of the present invention, the test circuit 13 performs the above-mentioned simultaneous read-out operation on at least two of the memory macros 11a, 11b, . . . , and 11n.

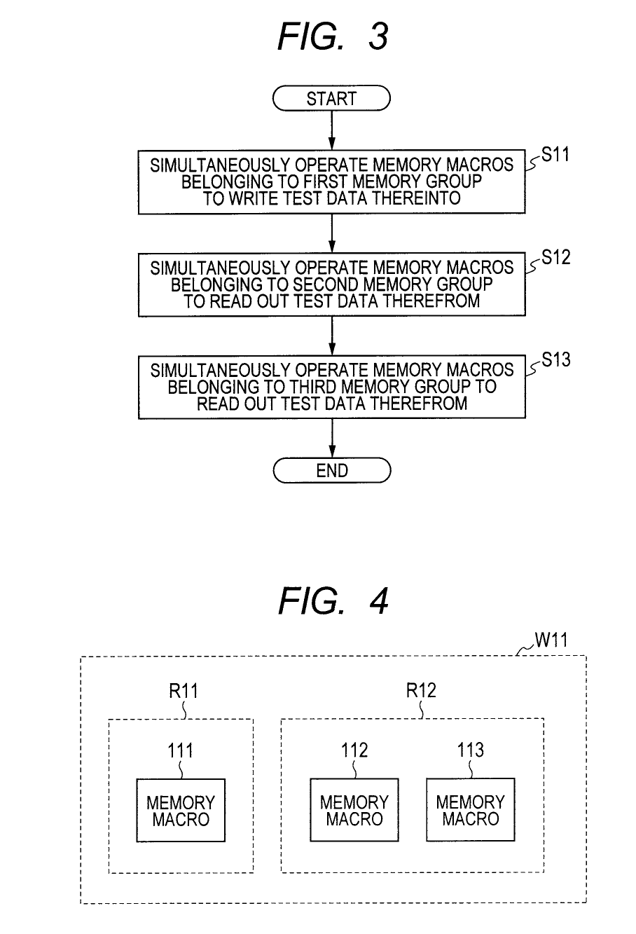

Referring to FIG. 3, there is shown a flowchart of procedural steps of a memory macro test method according to the first embodiment of the present invention. The memory macro test method according to the first embodiment of the present invention is applicable to inspection of the semiconductor integrated circuit 1 having multiple memory macros. Further, regarding selection from the memory macros in the memory macro test method according to the first embodiment of the present invention, the number of memory macros to be selected in execution of a simultaneous read-out operation of written test data is smaller than the number of memory macros to be selected in execution of a simultaneous write-in operation of input test data.

First, in the semiconductor integrated circuit 1, at least two of the memory macros belonging to the first memory group are simultaneously operated to write test data thereinto (S11). That is, the operation control circuit 12 selectively activates the memory macros belonging to the first memory group. Then, the test circuit 13 writes test data into the memory macros thus activated.

For example, the operation control circuit 12 reads out information regarding definition of the first memory group from a register or the like, and issues the chip enable signal 32 indicating activation to the memory macros defined as members of the first memory group. That is, the operation control circuit 12 conducts control to activate the memory macros concerned by using the chip enable signal 32. Thus, the memory macros concerned are activated for operation thereof. Then, the test circuit 13 attempts to perform simultaneous writing of test data with respect to the memory macros 11a, 11b, . . . , and 11n. At this time, among the memory macros 11a, 11b, . . . , and 11n, only the memory macros belonging to the first memory group, i.e., only the memory macros in activated states are operated. Hence, test data can be written into only the memory macro belonging to the first memory group.

Then, in the semiconductor integrated circuit 1, a simultaneous read-out operation is performed on the second memory group of partial memory macros included in the first memory group to read out test data from the second memory group (S12). That is, after completion of simultaneous write-in processing of test data by the test circuit 13, the operation control circuit 12 selectively activates, as a group of operation objects of simultaneous read-out processing, the second memory group of partial memory macros included in the first memory group of memory macros that have been specified as operation objects of simultaneous write-in processing. Then, the test circuit 13 reads out test data from the second memory group of partial memory macros thus activated.

For example, after the test circuit 13 completes simultaneous write-in processing of test data in step S11, the operation control circuit 12 reads out information regarding definition of the second memory group from a register or the like, and issues the chip enable signal 32 indicating activation to the memory macros defined as members of the second memory group. That is, the operation control circuit 12 conducts control to activate the memory macros concerned by using the chip enable signal 32. Thus, the memory macros concerned are activated for operation thereof. At this time, to other memory macros than those of the second memory group, the operation control circuit 12 also issues the chip enable signal 32 indicating deactivation thereof. That is, the operation control circuit 12 conducts control to deactivate the other memory macros by using the chip enable signal 32. Thus, the other memory macros are deactivated. Then, the test circuit 13 attempts to perform simultaneous reading of test data with respect to the memory macros 11a, 11b, . . . , and 11n. At this time, among the memory macros 11a, 11b, . . . , and 11n, only the memory macros belonging to the second memory group, i.e., only the memory macros in activated states are operated. Hence, test data can be read out of only the memory macros belonging to the second memory group.

Then, in the semiconductor integrated circuit 1, a simultaneous read-out operation is performed on a third memory group of partial memory macros included in the first memory group, which are partial memory macros not belonging to the second memory group, to read out test data from the third memory group (S13). For example, after the test circuit 13 completes simultaneous read-out processing of test data in step S12, the operation control circuit 12 reads out information regarding definition of the third memory group from a register or the like, and issues the chip enable signal 32 indicating activation to the memory macros defined as members of the third memory group. That is, the operation control circuit 12 conducts control to activate the memory macros concerned by using the chip enable signal 32. Thus, the memory macros concerned are activated for operation thereof. At this time, to the memory macros belonging to the second memory group, the operation control circuit 12 also issues the chip enable signal 32 indicating deactivation thereof. That is, the operation control circuit 12 conducts control to deactivate the memory macros belonging to the second memory group by using the chip enable signal 32. Thus, the memory macros belonging to the second memory group are deactivated. Then, the test circuit 13 attempts to perform simultaneous reading of test data in a manner similar to that in step S12. At this time, test data can be read out of only the memory macros belonging to the third memory group, i.e., no test data is read out of the memory macros belonging to the second memory group.

As described above, in the test method for inspecting the semiconductor integrated circuit 1 having multiple memory macros according to the first embodiment of the present invention, the number of memory macros to be selected from the memory macros in execution of a simultaneous read-out operation of written test data is smaller than the number of memory macros to be selected in execution of a simultaneous write-in operation of input test data. Hence, the amount of power noise in simultaneous read-out processing can be decreased relatively to that in simultaneous write-in processing. Thus, even in simultaneous read-out processing wherein a noise margin is relatively small, it is possible to obtain accurate test results.

### Working Example 1

The following describes a working example 1 of the first embodiment of the present invention. The operation control circuit 12 according to the working example 1 of the present invention selects, as a group of operation objects of simultaneous write-in processing, a first memory group that includes all the memory macros contained in the semiconductor integrated circuit 1. That is, at the time of execution of writing test data into memory macros, all the memory macros are simultaneously operated in the working example 1 of the present invention.

Thus, a period of time required for write-in processing can be minimized. Further, at the time of execution of read-out processing, a smaller number of memory macros than the number of memory macros belonging to the first memory group are simultaneously operated, i.e., not all the memory macros are simultaneously operated. Hence, it is possible to obtain accurate test results as described above with respect to the first embodiment of the present invention.

Referring to FIG. 4, there is shown an example of memory macro selection according to the working example 1 of the present invention. In the description given below, it is assumed that a memory group W11 shown in FIG. 4 is defined as a first memory group. All of memory macros 111, 112, and 113 are arranged to belong to the memory group W11. A memory group R11 shown in FIG. 4 is defined as a second memory group, and a memory group R12 shown in FIG. 4 is defined as a third memory group. Only the memory macro 111 is arranged to belong to the memory group R11, and the memory macros 112 and 113 are arranged to belong to the memory group R12. At least in principle, a memory group to be selected as a group of read-out objects includes any partial memory macro belonging to the memory group W11 defined as the first memory group. It is also to be noted that the memory macros may be grouped as read-out objects differently from the case mentioned above, i.e., any memory macro may be arranged to belong to any memory group to be selected as a group of read-out objects. For example, the memory macros 111 and 112 may be arranged to belong to the memory group R11, and only the memory macro 113 may be arranged to belong to the memory group R12.

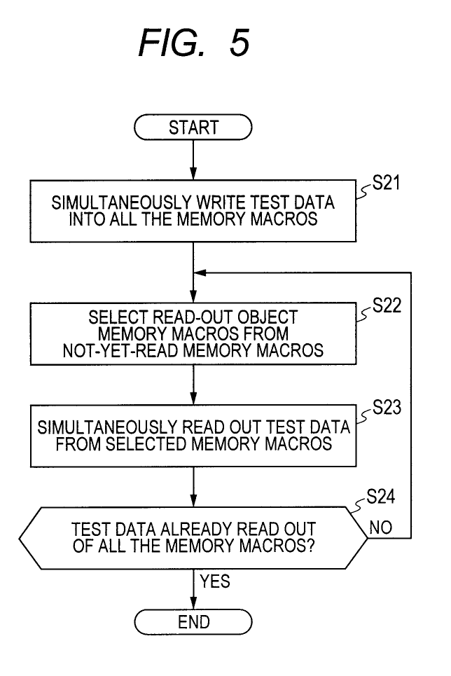

Referring to FIG. 5, there is shown a flowchart of procedural steps of a memory macro test method according to the working example 1 of the present invention. First, in the semiconductor integrated circuit 1, test data is simultaneously written into all the memory macros (S21). That is, in the semiconductor integrated circuit 1, all the memory macros that are arranged to belong to the first memory group are simultaneously operated to write test data thereinto. For example, the operation control circuit 12 reads out information regarding definition of the memory group W11 from a register or the like, and issues the chip enable signal 32 indicating activation to the memory macros 111, 112, and 113 defined as members of the memory group W11. That is, the operation control circuit 12 conducts control to activate the memory macros 111, 112, and 113 by using the chip enable signal 32. Thus, the memory macros 111, 112, and 113 are activated for operation thereof. Thereafter, the test circuit 13 carries out processing in a manner similar to that in step S11 shown in FIG. 3. Since all the memory macros 111, 112, and 113 are simultaneously operated as mentioned above, it is allowed to write test data into all the memory macros. Thus, a period of time required for write-in processing can be minimized.

Then, in the semiconductor integrated circuit 1, a read-out object memory macro is selected from not-yet-read memory macros (S22). Note that, in this step of operation in the semiconductor integrated circuit 1, any partial memory macro that has been subjected to write-in processing in step S21 is selected, i.e., not all the memory macros are selected. For example, after completion of test data write-in processing by the test circuit 13 in step S22, the operation control circuit 12 reads out information regarding definition of the memory group R11 from a register or the like, and issues the chip enable signal 32 indicating activation to the memory macro 111 defined as a member of the memory group R11. That is, the operation control circuit 12 conducts control to activate the memory macro 111 by using the chip enable signal 32. Thus, the memory macro 111 is activated for operation thereof. At this time, to the memory macros 112 and 113 with the exclusion of the memory macro 111, the operation control circuit 12 also issues the chip enable signal 32 indicating deactivation thereof. That is, the operation control circuit 12 conducts control to deactivate the memory macros 112 and 113 by using the chip enable signal 32. Thus, the memory macros 112 and 113 are deactivated for stoppage of operation thereof.

Then, in the semiconductor integrated circuit 1, test data is simultaneously read out of selected memory macros (S23). For example, the test circuit 13 simultaneously reads out test data from read-out object memory macros. In this example, since only the memory macro 111 belonging to the memory group R11 is operated, test data is read out of only the memory macro 111. Hence, the number of memory macros operated simultaneously in step S23 is smaller than that in step S21. Thus, an adverse effect of power noise can be alleviated, and hence it is possible to obtain accurate test results. Further, there may be provided such an arrangement that the test circuit 13 retains information indicating already-read states of respective memory macros that have been subjected to test data read-out processing.

Then, in the semiconductor integrated circuit 1, it is judged whether test data has already been read out of all the memory macros (S24). For example, through reference to the above-mentioned information indicating already-read states of respective memory macros, the operation control circuit 12 forms a judgment on whether there is a not-yet-read memory macro among all the memory macros that have been subjected to test data write-in processing in step S21. If a not-yet-read memory macro is found in step S24, program control loops back to step S22.

Then, in step S22, the operation control circuit 12 selects the memory group R12, for example. More specifically, the operation control circuit 12 reads out information regarding definition of the memory group R12 from a register or the like, and issues the chip enable signal 32 indicating activation to the memory macros 112 and 113 defined as members of the memory group R12. That is, the operation control circuit 12 conducts control to activate the memory macros 112 and 113 by using the chip enable signal 32. Thus, the memory macros 112 and 113 are activated for operation thereof. At this time, to the memory macro 111 not belonging to the memory group R12, the operation control circuit 12 also issues the chip enable signal 32 indicating deactivation thereof. That is, the operation control circuit 12 conducts control to deactivate the memory macro 111 by using the chip enable signal 32. Thus, the memory macro 111 is deactivated for stoppage of operation thereof. Thereafter, in the semiconductor integrated circuit 1, steps S22, S23, and S24 are repeatedly carried out until completion of read-out processing of all the memory macros.

In step S24, if it is found that there remains no memory macro that has not yet been subjected to test data read-out processing, i.e., if it is found that test data has already been read out of all the memory macros, then the memory macro test comes to an end in the semiconductor integrated circuit 1.

As described above with respect to the working example 1 of the present invention, it is possible to obtain accurate test results while minimizing a period of time required for write-in processing.

### Working Example 2

Then, the following describes a working example 2 of the first embodiment of the present invention. According to the working example 2 of the present invention, after completion of test data writing into a first memory group by the test circuit 13, the operation control circuit 12 further selects, as a group of operation objects of simultaneous write-in processing, a fourth memory group of memory macros not belonging to the first memory group. In this selection, the number of memory macros belonging to a second memory group is smaller than the number of memory macros belonging to the first memory group and also smaller than the number of memory macros belonging to the fourth memory group.

That is, according to the working example 2 of the present invention, at the time of execution of writing test data into multiple memory macros, the memory macros are ranged into multiple memory groups, and memory macros belonging to each memory group are simultaneously operated. The number of memory macros belonging to each memory group in execution of test data write-in processing is larger than the number of memory macros to be simultaneously operated in execution of test data read-out processing.

In other words, the operation control circuit 12 according to the working example 2 of the present invention selects operation-object memory macros in execution of simultaneous write-in processing for each of multiple memory groups in such a fashion that multiple memory macros are arranged to belong to any memory group. The number of memory macros belonging to each memory group to be selected as operation objects in execution of simultaneous write-in processing is larger than the number of memory macros to be selected as operation objects in execution of simultaneous read-out processing.

Thus, an adverse effect of power noise can be reduced in simultaneous write-in processing. Since the number of operation objects of simultaneous read-out processing is smaller than the operation objects of simultaneous write-in processing, an adverse effect of power noise can also be reduced in simultaneous read-out processing. Hence, it is possible to obtain accurate test results.

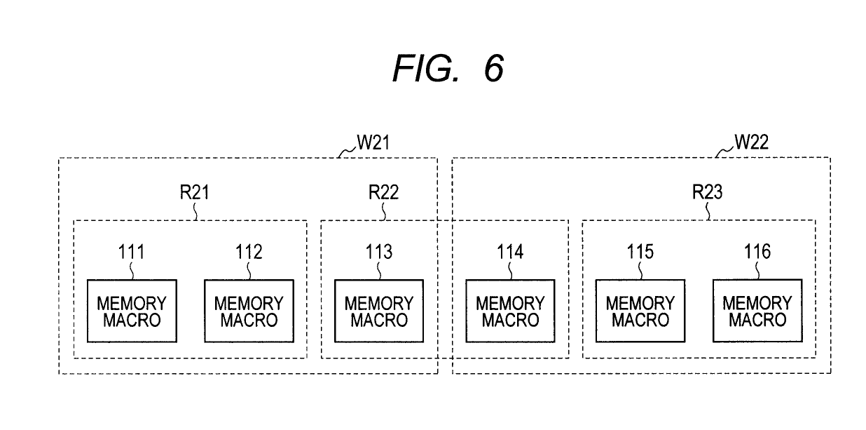

Referring to FIG. 6, there is shown an example of memory macro selection according to the working example 2 of the present invention. In the description given below, it is assumed that memory groups W21 and W22 shown in FIG. 6 are defined as write-in object memory groups. Memory macros 111, 112, and 113 are arranged to belong to the memory group W21, and memory macros 114, 115, and 116 are arranged to belong to the memory group W22. That is, multiple memory groups are provided as write-in object memory groups, and at least two memory macros are arranged to belong to each write-in object memory group. Further, memory groups R21, R21, and R23 are defined as read-out object memory groups. The memory macros 111 and 112 are arranged to belong to the memory group R21, the memory macros 113 and 114 are arranged to belong to the memory group R22, and the memory macros 115 and 116 are arranged to belong to the memory group R23. That is, at least three memory groups are defined as read-out object memory groups, and the number of memory macros belonging to each read-out object memory group is smaller than the number of memory macros belonging to each write-in object memory group.

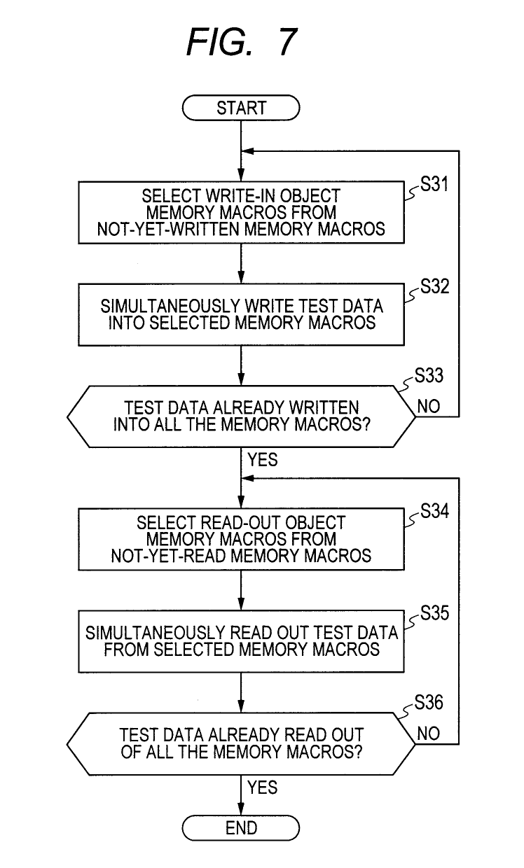

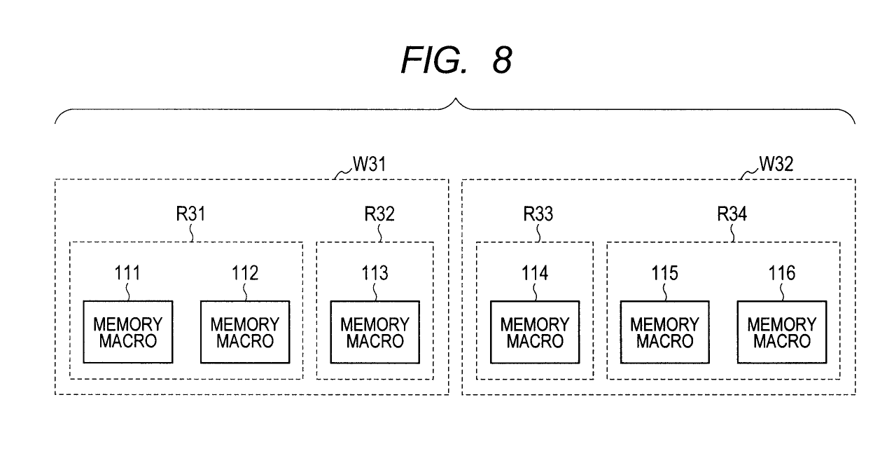

Referring to FIG. 7, there is shown a flowchart of procedural steps of a memory macro test method according to the working example 2 of the present invention. First, in the semiconductor integrated circuit 1, write-in object memory macros are selected from not-yet-written memory macros (S31). Note that, in this step of operation in the semiconductor integrated circuit 1, at least two partial memory macros are selected from the memory macros 111 to 116, i.e., not all the memory macros are selected. More specifically, it is conditioned that at least two memory macros are left unselected in the first cycle of test data writing in the semiconductor integrated circuit 1, and that at least two memory macros of not-yet-written memory macros are selected in each of the second and subsequent cycles of test data writing in the semiconductor integrated circuit 1. Thus, write-in processing can be carried out on multiple write-in object memory macros with high efficiency, contributing to reduction in test time.

For example, in the first cycle of test data write-in processing, the operation control circuit 12 reads out information regarding definition of the memory group W21 from a register or the like, and issues the chip enable signal 32 indicating activation to the memory macros 111 and 112 defined as members of the memory group W21. That is, the operation control circuit 12 conducts control to activate the memory macros 111 and 112 by using the chip enable signal 32. Thus, the memory macros 111 and 112 are activated for operation thereof. At this time, to the memory macros 114 to 116 not belonging to the memory group W21, the operation control circuit 12 also issues the chip enable signal 32 indicating deactivation thereof. That is, the operation control circuit 12 conducts control to deactivate the memory macros 114 to 116 by using the chip enable signal 32. Thus, the memory macros 114 to 116 are deactivated for stoppage of operation thereof.

Then, in the semiconductor integrated circuit 1, test data is simultaneously written into selected memory macros (S32). For example, the test circuit 13 attempts to perform simultaneous writing of test data with respect to the memory macros 111 to 116. In this example, only the memory macros belonging to the memory group W21 are operated among the memory macros 111 to 116, i.e., only the memory macros 111 and 112 in activated states are operated. Hence, test data is written into the memory macros belonging to the memory group W21. Further, there may be provided such an arrangement that the test circuit 13 retains information indicating already-written states of respective memory macros that have been subjected to test data write-in processing.

Then, in the semiconductor integrated circuit 1, it is judged whether test data has already been written into all the memory macros (S33). For example, through reference to the above-mentioned information indicating already-written states of respective memory macros, the operation control circuit 12 forms a judgment on whether there is a not-yet-written memory macro among all the memory macros to be subjected to test data writing in step S32, which should be repeated as required. If a not-yet-written memory macro is found in step S33, program control loops back to step S31.

Then, in step S31 in the second cycle of test data write-in processing for example, the operation control circuit 12 reads out information regarding definition of the memory group W22 from a register or the like, and issues the chip enable signal 32 indicating activation to the memory macros 113 and 114 defined as members of the memory group W22. That is, the operation control circuit 12 conducts control to activate the memory macros 113 and 114 by using the chip enable signal 32. Thus, the memory macros 113 and 114 are activated for operation thereof. At this time, to the memory macros 111, 112, 115, and 116 not belonging to the memory group W22, the operation control circuit 12 also issues the chip enable signal 32 indicating deactivation thereof. That is, the operation control circuit 12 conducts control to deactivate the memory macros 111, 112, 115, and 116 by using the chip enable signal 32. Thus, the memory macros 111, 112, 115, and 116 are deactivated for stoppage of operation thereof. Thereafter, in the semiconductor integrated circuit 1, steps S31, S32, and S33 are repeatedly carried out until completion of write-in processing of all the memory macros.

In step S33, if it is found that there remains no memory macro that has not yet been subjected to test data write-in processing, i.e., if it is found that test data has already been written into all the memory macros, then program control goes to step S34. Thereafter, in steps S34 to S36, test data read-out processing is carried out in a manner similar to that in steps S22 to S24 shown in FIG. 5. For the sake of avoiding duplicative descriptions, no details of steps S34 to S36 are given here.

As described above with respect to the working example 2 of the present invention, it is possible to obtain accurate test results while reducing an adverse effect of power noise in test data write-in processing.

### Working Example 3

Then, the following describes a working example 3 of the first embodiment of the present invention. According to the working example 3 of the present invention, with respect to one write-in processing operation, multiple divided read-out processing operations are carried out repeatedly as required. Thus, a memory macro test can be conducted on the basis of each memory group including multiple memory macros, thereby allowing easy planning of memory macro test implementation.

That is, the operation control circuit 12 according to the working example 3 of the present invention selects operation-object memory macros in execution of simultaneous write-in processing for each of multiple memory groups in such a fashion that multiple memory macros are arranged to belong to any memory group. After completion of simultaneous write-in processing on one of the memory groups, an operation-object memory macro in simultaneous read-out processing is selected from memory macros belonging to the one memory group concerned.

In other words, the operation control circuit 12 according to the working example 3 of the present invention is provided in a modified form of the above-mentioned operation control circuit 12 of the working example 2 of the present invention. In essence, according to the working example 3 of the present invention, after completion of simultaneous write-in processing on one of memory groups, an operation object memory macro in simultaneous read-out processing is selected from memory macros belonging to the one memory group concerned.

For example, the operation control circuit 12 according to the working example 3 of the present invention selects, as a group of operation-objects of write-in processing, a first memory group of at last two memory macros from multiple memory macros contained in the semiconductor integrated circuit 1. Further, the operation control circuit 12 selects, as groups of operation objects of read-out processing, second and third memory groups of partial memory macros among the memory macros belonging to the first memory group.

Then, after the test circuit 13 completes read-out processing on the second and third memory groups, the operation control circuit 12 according to the working example 3 of the present invention selects, as a group of operation objects of write-in processing, a fourth memory group of memory macros not belonging to the first memory group. Further, the operation control circuit 12 selects, as groups of operation objects of read-out processing, fifth and sixth memory groups of partial memory macros among the memory macros belonging to the fourth memory group.

Referring to FIG. 8, there is shown an example of memory macro selection according to the working example 3 of the present invention. In the description given below, it is assumed that memory groups W31 and W32 shown in FIG. 8 are defined as write-in object memory groups. Memory macros 111, 112, and 113 are arranged to belong to the memory group W31, and memory macros 114, 115, and 116 are arranged to belong to the memory group W32. That is, multiple memory groups are provided as write-in object memory groups, and at least two memory macros are arranged to belong to each write-in object memory group. Further, memory groups R31, R32, R33, and R34 are defined as read-out object memory groups. The memory macros 111 and 112 are arranged to belong to the memory group R31, only the memory macro 113 is arranged to belong to the memory group R32, only the memory macro 114 is arranged to belong to the memory group R33, and the memory macros 115 and 116 are arranged to belong to the memory group R34. That is, no read-out object memory group is formed across the write-in object memory groups. Further, at least two read-out object memory groups are defined with respect to each write-in object memory group. Hence, the number of memory macros belonging to each read-out object memory group is less than the number of memory macros belonging to each write-in object memory group.

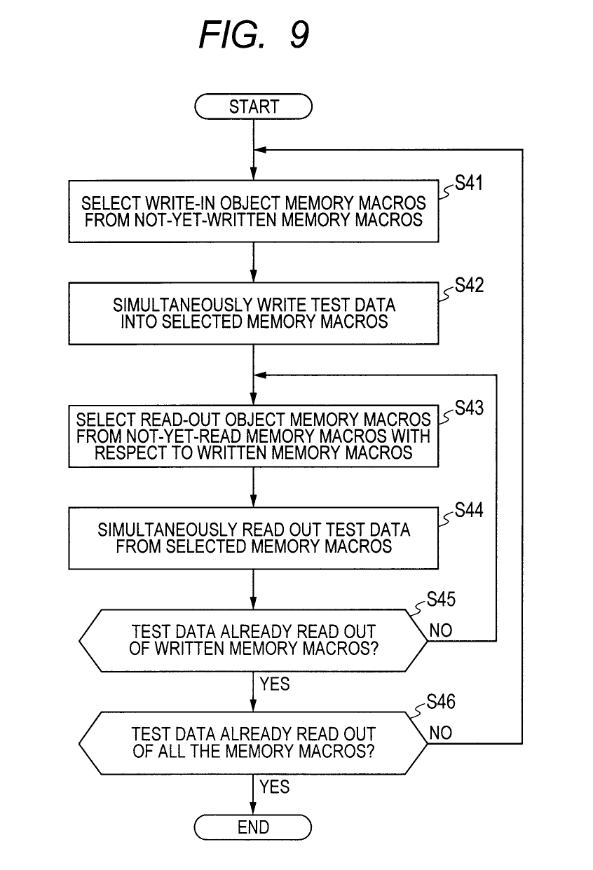

Referring to FIG. 9, there is shown a flowchart of procedural steps of a memory macro test method according to the working example 3 of the present invention. In the following description, the details of processing operations equivalent to those shown in FIGS. 3, 5, and 7 are omitted wherever appropriate for the sake of clarity. First, processing operations in steps S41 and S42 shown in FIG. 9 are carried out in a manner similar to those in steps S31 and S32 shown in FIG. 7.

Then, with respect to written memory macros in the semiconductor integrated circuit 1, read-out object memory macros are selected from not-yet-read memory macros (S43). For example, in a situation where test data has already been written into the memory group W31 by the test circuit 13, the operation control circuit 12 selects the memory group R31 of partial memory macros belonging to the memory group W31. More specifically, the operation control circuit 12 reads out information regarding definition of the memory group R31 from a register or the like, and issues the chip enable signal 32 indicating activation to the memory macros 111 and 112 defined as members of the memory group R31. That is, the operation control circuit 12 conducts control to activate the memory macros 111 and 112 by using the chip enable signal 32. Thus, the memory macros 111 and 112 are activated for operation thereof. At this time, to all of the memory macros 113 to 116 not belonging to the memory group R31, the operation control circuit 12 also issues the chip enable signal 32 indicating deactivation thereof. That is, the operation control circuit 12 conducts control to deactivate the memory macros 113 to 116 by using the chip enable signal 32. Thus, the memory macros 113 to 116 are deactivated for stoppage operation thereof.

Subsequently, in the semiconductor integrated circuit 1, test data is simultaneously read out of the selected memory macros 111 and 112 (S44). Step S44 is performed similarly to step S35 shown in FIG. 7.

Then, in the semiconductor integrated circuit 1, it is judged whether test data has already been read out of the memory macros 111 to 113 belonging to the written memory group W31 (S45). For example, through reference to information indicating already-read states of respective memory macros, the operation control circuit 12 forms a judgment on whether there is a not-yet-read memory macro among all the memory macros that have been subjected to test data write-in processing in step S42, i.e., among all the memory macros belonging to the first memory group. If a not-yet-read memory macro is found in step S45, program control loops back to step S43.

Then, in step S43, the operation control circuit 12 selects the memory group R32 that includes any partial memory macro belonging to the memory group W31, for example. More specifically, the operation control circuit 12 reads out information regarding definition of the memory group R32 from a register or the like, and issues the chip enable signal 32 indicating activation to the memory macro 113 defined as a member of the memory group R32. That is, the operation control circuit 12 conducts control to activate the memory macro 113 by using the chip enable signal 32. Thus, the memory macro 113 is activated for operation thereof. At this time, to all of the memory macros 111, 112, 114, 115, and 116 not belonging to the memory group R32, the operation control circuit 12 also issues the chip enable signal 32 indicating deactivation thereof. That is, the operation control circuit 12 conducts control to deactivate the memory macros 111, 112, 114, 115, and 116 by using the chip enable signal 32. Thus, the memory macros 111, 112, 114, 115, and 116 are deactivated for stoppage of operation thereof. In a case where memory macros other than the memory macros 111 to 113 are arranged to belong to the memory group W31 in the semiconductor integrated circuit 1, steps S43, S44, and S45 are repeatedly carried out until completion of read-out processing of all the not-yet-read memory macros belonging to the memory group W31.

In step S45, with respect to the written memory macros, if it is found that there remains no memory macro that has not yet been subjected to test data read-out processing, i.e., if it is found that test data has already been read out of the written memory macros, then program control goes to step S46.

Then, in the semiconductor integrated circuit 1, it is judged whether test data has already been read out of all the memory macros (S46). A judgment in step S46 is made in a manner similar to that in step S24 shown in FIG. 5. Note that, if a not-yet-read memory macro is found in step S46, program control loops back to step S41.

Then, in step S41, the operation control circuit 12 selects the memory group W32, for example. More specifically, the operation control circuit 12 reads out information regarding definition of the memory group W32 from a register or the like, and issues the chip enable signal 32 indicating activation to the memory macros 114 to 116 defined as members of the memory group W32. That is, the operation control circuit 12 conducts control to activate the memory macros 114 to 116 by using the chip enable signal 32. Thus, the memory macros 114 to 116 are activated for operation thereof. At this time, to all of the memory macros 111 to 113 not belonging to the memory group W32, the operation control circuit 12 also issues the chip enable signal 32 indicating deactivation thereof. That is, the operation control circuit 12 conducts control to deactivate the memory macros 111 to 113 by using the chip enable signal 32. Thus, the memory macros 111 to 113 are deactivated for stoppage of operation thereof. Thereafter, in the semiconductor integrated circuit 1, steps S41 to S46 are repeatedly carried out until completion of write-in processing and read-out processing of all the memory macros.

In step S46, if it is found that there remains no memory macro that has not yet been subjected to test data read-out processing, i.e., if it is found that test data has already been read out of all the memory macros, then the memory macro test comes to an end in the semiconductor integrated circuit 1.

As described above with respect to the working example 3 of the present invention, it is possible to obtain accurate test results while reducing an adverse effect of power noise in test data write-in processing and read-out processing. Further, a memory macro test can be conducted on the basis of each memory group including multiple memory macros, thereby allowing easy planning of memory macro test implementation.

### Other Embodiments

Just for the purpose of decreasing a test time required for inspecting multiple memory macros, it may be conditioned that the number of memory macros to be operated simultaneously in test data write-in processing is equal to that in test data read-out processing. However, under this condition, even if no adverse effect of power noise occurs in write-in processing, there is a high degree of possibility that an adverse effect may be brought about in read-out processing. For example, the memory cell 22 and the sense amplifier 24 are likely to be affected adversely by power noise on an LSI power supply line.

To obviate such a disadvantage as mentioned above, an operation timing of read-out processing is shifted with respect of that of write-in processing, at least in principle, according to the preferred embodiments of the present invention. This arrangement makes it possible to prevent the occurrence of superposition of chip-level noises among memory macros, i.e., to prevent the occurrence of superposition of noises propagating through a power supply line disposed among memory macros.

Note that, in simultaneous operation of memory macros in the present invention, it is not necessarily required to issue read-out instructions to the memory macros at the same time. More specifically, in simultaneous operation of the memory macros, a timing sequence of signaling from the memory cell 22 to the sense amplifier 24 through the bit line 27 (FIG. 2) is performed simultaneously among the memory macros. According to the preferred embodiments of the present invention, at the time of read-out processing on the memory macros, it is just required to decrease the number of memory macros to be operated simultaneously in the same time frame in propagation of a signal having a relatively small difference potential through the bit line 27, at least in principle.

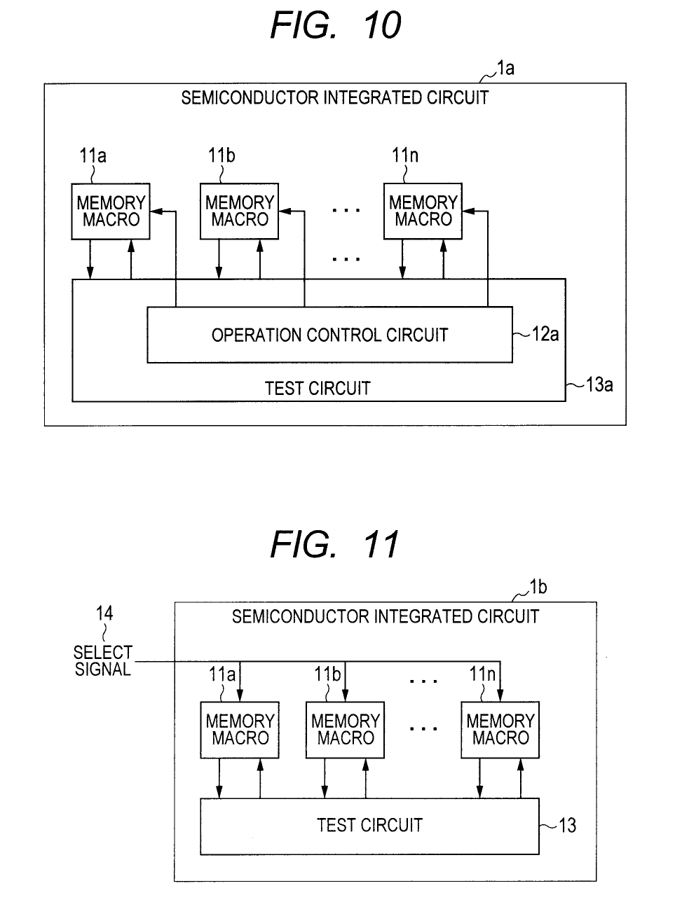

As regards the test circuit 13 according to the first embodiment of the present invention, there may be provided such an arrangement that the functions of the operation control circuit 12 are incorporated in the test circuit 13, as exemplarily illustrated in FIG. 10. Referring to FIG. 10, there is shown a block diagram of a configuration of a semiconductor integrated circuit 1a according to a second embodiment of the present invention. In the semiconductor integrated circuit 1a, a test circuit 13a incorporates an operation control circuit 12a having functions equivalent to those of the operation control circuit 12. Since the operations of the semiconductor integrated circuit 1a are equivalent to the above-mentioned operations of the semiconductor integrated circuit 1 according to the first embodiment of the present invention, no repetitive detailed description thereof is given here.

Further, there may also be provided a modified arrangement wherein a select signal for selecting a predetermined memory group is accepted under control of an instruction from circuitry external to the semiconductor integrated circuit concerned, and wherein, in accordance with the instruction, test data is written into the selected memory group, as exemplarily illustrated in FIG. 11. Referring to FIG. 11, there is shown a block diagram of a configuration of a semiconductor integrated circuit 1b according to a third embodiment of the present invention. In the semiconductor integrated circuit 1b, a select signal 14 for selecting a memory group to be operated under external control is accepted as an input signal. In accordance with the select signal 14 thus accepted, it is determined whether or not to operate memory macros 11a, 11b, 11n. Note that, in this arrangement, a circuit equivalent to the operation control circuit 12 may not be contained in the semiconductor integrated circuit 1b. Since the other operations of the semiconductor integrated circuit 1b are equivalent to the above-mentioned operations of the semiconductor integrated circuit 1 according to the first embodiment of the present invention, no repetitive detailed description thereof is given here.

Still further, it is to be understood that the present invention is not limited to the preferred embodiments and examples in the foregoing description and that various changes and modifications may be made in the present invention without departing from the spirit and scope thereof.

What is claimed is:

1. A semiconductor integrated circuit test method for inspecting a semiconductor integrated circuit having a plurality memory macros, comprising the steps of:
performing a simultaneous write-in operation in which test data is simultaneously written into the memory macros; and
performing a simultaneous read-out operation in which written test data is simultaneously read out of the memory macros;
wherein the number of memory macros to be selected in execution of the simultaneous read-out operation is smaller than the number of memory macros to be selected in execution of the simultaneous write-in operation.

2. The semiconductor integrated circuit test method according to claim 1,
wherein each of the memory macros comprises a memory cell for storing data for each address, a write amplifier for receiving input data from external circuitry and for feeding the received input data to the memory cell through a bit line, and a sense amplifier for receiving output data from the memory cell through a bit line and for outputting the received output data to the external circuitry,
wherein, in the simultaneous write-in operation, there are simultaneously performed write-in operations, each including a series of actions in which a write-in object region in the memory cell specified by each address is identified, the write amplifier receives input data to be written from the external circuitry, and then the input data is set up in the identified write-in object region through the bit line, and
wherein, in the simultaneous read-out operation, there are simultaneously performed read-out operations, each including a series of actions in which a read-out object region in the memory cell specified by each address is identified, the sense amplifier receives output data stored in the identified read-out object region from the memory cell through the bit line, and then the sense amplifier outputs the received output data to the external circuitry.

3. The semiconductor integrated circuit test method according to claim 1,
wherein, after completion of the simultaneous write-in operation, as a group of objects of the simultaneous read-out operation, there is selected a second memory group of partial memory macros included in a first memory group of memory macros that have been subjected to the simultaneous write-in operation, and
wherein, after completion of the simultaneous read-out operation on the second memory group, as a group of objects of the simultaneous read-out operation, there is selected a third memory group of partial memory macros included in the first memory group except the memory macros belonging to the second memory group.

4. The semiconductor integrated circuit test method according to claim 1,
wherein all the memory macros are selected as objects of the simultaneous write-in operation.

5. The semiconductor integrated circuit test method according to claim 1,
wherein, in a case where the memory macros are arranged into a plurality of memory groups, and where memory macros belonging to each memory group are subjected to the simultaneous write-in operation, the number of memory macros belonging to each memory group to be selected in execution of the simultaneous write-in operation is larger than the number of memory macros to be selected in execution of the simultaneous read-out operation.

6. The semiconductor integrated circuit test method according to claim 5,
wherein, after completion of the simultaneous write-in operation on one of the memory groups, memory macros to be subjected to the simultaneous read-out operation are selected from the memory macros belonging to the one memory group that has been subjected to the simultaneous write-in operation.

7. The semiconductor integrated circuit test method according to claim 1,
wherein, in a case where the memory macros are arranged into a plurality of memory groups, and where memory macros belonging to each memory group are subjected to the simultaneous write-in operation, after completion of the simultaneous write-in operation on one of the memory groups, memory macros to be subjected to the simultaneous read-out operation are selected from the memory macros belonging to the one memory group that has been subjected to the simultaneous write-in operation.

8. A semiconductor integrated circuit having a plurality of memory macros, the semiconductor integrated circuit comprising:
an operation control circuit for selecting operation-object memory macros from the memory macros; and
a test circuit for carrying out simultaneous write-in processing in which test data is simultaneously written into operation-object memory macros selected by the operation control circuit, and for carrying out simultaneous read-out processing in which test data is simultaneously read out of operation-object memory macros selected by the operation control circuit;
wherein the number of operation-object memory macros to be selected by the operation control circuit in execution of the simultaneous read-out processing is smaller than the number of operation-object memory macros to be selected by the operation control circuit in execution of the simultaneous write-in processing.

9. The semiconductor integrated circuit according to claim 8,
wherein each of the memory macros comprises a memory cell for storing data for each address, a write amplifier for receiving input data from external circuitry and for feeding the received input data to the memory cell through a bit line, and a sense amplifier for receiving output data from the memory cell through a bit line and for outputting the received output data to the external circuitry,
wherein, in the simultaneous write-in processing, there are simultaneously performed write-in processing sequences, each including a series of actions in which a write-in object region in the memory cell specified by each address is identified, the write amplifier receives input data to be written from the external circuitry, and then the input data is set up in the identified write-in object region through the bit line, and
wherein, in the simultaneous read-out processing, there are simultaneously performed read-out processing sequences, each including a series of actions in which a read-out object region in the memory cell specified by each address is identified, the sense amplifier receives output data stored in the identified read-out object region from the memory cell through the bit line, and then the sense amplifier outputs the received output data to the external circuitry.

10. The semiconductor integrated circuit according to claim 8,
wherein, after completion of the simultaneous write-in processing, the operation control circuit selects, as a group of operation objects of the simultaneous read-out processing, a second memory group of partial memory macros included in a first memory group of memory macros that have been subjected to the simultaneous write-in processing, and
wherein, after completion of the simultaneous read-out processing on the second memory group, the operation control circuit selects, as a group of operation objects of the simultaneous read-out processing, a third memory group of partial memory macros included in the first memory group except the memory macros belonging to the second memory group.

11. The semiconductor integrated circuit according to claim 8,
wherein the operation control circuit selects all the memory macros as operation objects of the simultaneous write-in processing.

12. The semiconductor integrated circuit according to claim 8,
wherein the operation control circuit selects operation-object memory macros in execution of the simultaneous write-in processing for each of the memory groups in such a fashion that the memory macros are arranged to belong to any memory group, and
wherein the number of memory macros belonging to each memory group to be selected as operation objects in execution of the simultaneous write-in processing is larger than the number of memory macros to be selected as operation objects in execution of the simultaneous read-out processing.

13. The semiconductor integrated circuit according to claim 12,
wherein, after completion of the simultaneous write-in processing on one of the memory groups, the operation control circuit selects operation-object memory macros to be subjected to the simultaneous read-out processing from the memory macros belonging to the one memory group that has been subjected to the simultaneous write-in processing.

14. The semiconductor integrated circuit according to claim 8,
wherein the operation control circuit selects operation-object memory macros in execution of the simultaneous write-in processing for each of the memory groups in such a fashion that the memory macros are arranged to belong to any memory group, and
wherein, after completion of the simultaneous write-in processing on one of the memory groups, operation-object memory macros to be subjected to the simultaneous read-out processing are selected from the memory macros belonging to the one memory group that has been subjected to the simultaneous write-in processing.

15. The semiconductor integrated circuit according to claim 8,
wherein each of the memory macros is provided in the form of a static random access memory.
